(19) United States
(12) Patent Application Publication
(10) Pub. No.: US 2009/0091536 A1
(43) Pub. Date: Apr. 9, 2009

(54) Dial Pad Data Entry

(75) Inventor: David M. Callaghan, Kirkland, WA (US)

Correspondence Address: MERCHANT & GOULD (MICROSOFT), P.O. BOX 2903, MINNEAPOLIS, MN, 55402-0903, US

(73) Assignee: MICROSOFT CORPORATION, Redmond, WA (US)

(21) Appl. No.: 11/868,298

(22) Filed: Oct. 5, 2007

(51) Int. Cl. G06F 3/02; H03K 17/94

(52) U.S. Cl. 345/168; 341/34

(57) ABSTRACT

Interpreting keystrokes from the key pad of a device incorporates both key touch and key stroke into the decision to display a character, advance a cursor or execute a command. The device contains switches capable of determining when a keystroke cycle is completed. The switches may include touch sensitive switches or two position switches. The touch sensitive switches detect when a user breaks touch contact with the switch. The two position switches detect the completion of the keystroke sequence when the switch is pressed into the second position. Several different types of touch sensitive switches can be used including capacitive coupled, light sensing, pressure sensing and heat sensing.

### BACKGROUND

Cellular telephones and other handheld electronic devices typically contain a dial pad for entering telephone numbers and other data. A typical dial pad contains 12 keys. Entry of alphabetic data into applications running on these devices often requires pressing a multi-function key multiple times, since the device lacks a QWERTY keyboard. For example, to enter the letter “A”, the “2” key is pressed one time, to enter the letter “B”, the “2” key is pressed two times, to enter the letter “C”, the “2” key is pressed three times and to enter the number “2”, the “2” key is pressed four times. During the keystroke sequence, there must be a way for the electronic device to determine the end of the multi-function key selection sequence, and thereby determine when the desired character is selected. A typical method is to wait a specified timeout period between keystrokes. If another keystroke on the same key is not detected by the end of this timeout period, the sequence is determined to be ended, the current value is entered, and the cursor is moved forward to accept the next input.

When a user enters keystrokes in this manner, the user typically does not know the value of this timeout period, and in addition, the timeout may vary between devices, especially those from different manufacturers. Therefore, the user typically guesses, i.e., waits a certain period of time after completing the keystroke sequence for a character, and then starts the keystroke sequence for the next character. Each time the user waits longer than necessary, time is wasted and text data input speed declines. However, if the user does not wait long enough, i.e., if the user starts the keystroke sequence for the next character before the time period has elapsed, the electronic device interprets the keystroke as part of the previous sequence. When this happens, the wrong character is displayed on the electronic device and the user is required to backspace and reenter the keystroke sequence for the desired character or, alternatively, the user must press the key repeatedly to alternate through all possible input values before being offered the desired value again.

Furthermore, when entering keystrokes in this manner, whenever the user pauses in the middle of an input sequence, the device assumes that the keystroke sequence is completed, whether it is or not. In addition, when input acceleration techniques such as T9 are used, entering an incorrect input value may result in several characters or entire words being entered unexpectedly. Ultimately, systems that use a fixed timeout of inactivity to differentiate between multifunction key input selection and advancing a cursor significantly limit the maximum data input rate.

### SUMMARY

Aspects of the present disclosure relate to improving the efficiency of processing keystrokes from the dial pad of a handheld communication device.

In one example, a dial pad contains touch sensitive switches coupled with mechanical switches for each input key. Each touch sensitive switch is configured to sense contact and identify when a user breaks touch contact with the mechanical switch. The breaking of touch contact with the switch signifies the completion of the keystroke sequence.

In another example, a dial pad contains two position switches. For a two position switch, pressing the switch half-way down constitutes a first switch position. Pressing the switch all the way down constitutes a second switch position. Releasing the switch from the first switch position after it has been pressed to the second switch position can be used as an indication that a keystroke sequence has been completed. Alternatively, pressing the switch to the second position can be used as indication that a keystroke sequence has been completed.

In another example, device manufacturers can provide customized software with their switches to further improve keystroke processing efficiency.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### DESCRIPTION OF THE DRAWINGS

The accompanying drawings incorporated in and forming a part of the specification illustrate several aspects of the present disclosure, and together with the description serve to explain the principles of the disclosure. In the drawings:

FIG. 1 is an illustration of an example communication device.

FIG. 2 is an illustration of an example dial pad switch configuration.

FIG. 3 is an illustration of an example dial pad containing touch sensitive switches.

FIG. 4 is an illustration of the internal operation of an example touch sensitive switch.

FIG. 5 is an illustration of an example dial pad containing two position switches.

FIG. 6 is an illustration of the internal operation of an example two position switch.

FIG. 7 is an illustration of functional modules of an example communication device.

FIG. 8 is an illustration of a flow chart for interpreting keystrokes from a dial pad using touch sensitive switches.

FIG. 9 is an illustration of a flow chart for interpreting keystrokes from a dial pad using two position switches.

FIG. 10 is an illustration of a flow chart for interpreting keystrokes from a dial pad using a touch button.

FIG. 11 is an illustration of a flow chart for monitoring and interpreting keystrokes in a communication device.

### DETAILED DESCRIPTION

The present application is directed to systems and methods that use switches that are configured to distinguish the last keystroke in a keystroke sequence. Two examples of such switches are touch sensitive switches and two position switches.

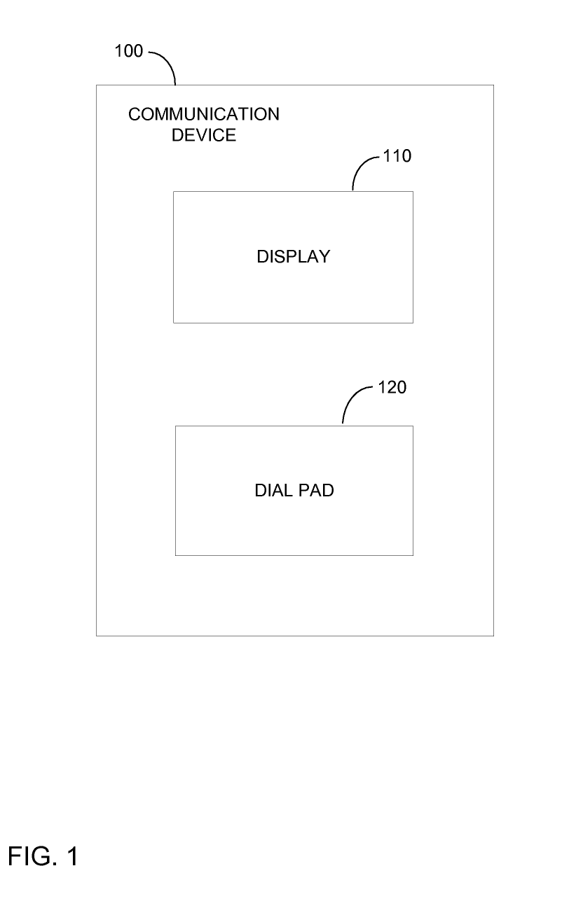

FIG. 1 shows an example electronic device 100 containing a display 110 and a dial pad 120. In example embodiments, the electronic device 100 is a handheld device. For example, the electronic device 100 can be a telecommunications device such as a cellular telephone, and/or can be Personal Data Assistant (PDA). Generally, the display 110 is configured to show alphanumeric characters, such as names and telephone numbers. The dial pad 120 includes a plurality of keys (sometimes referred to as switches) that allow the user to input numbers and letters, as described below.

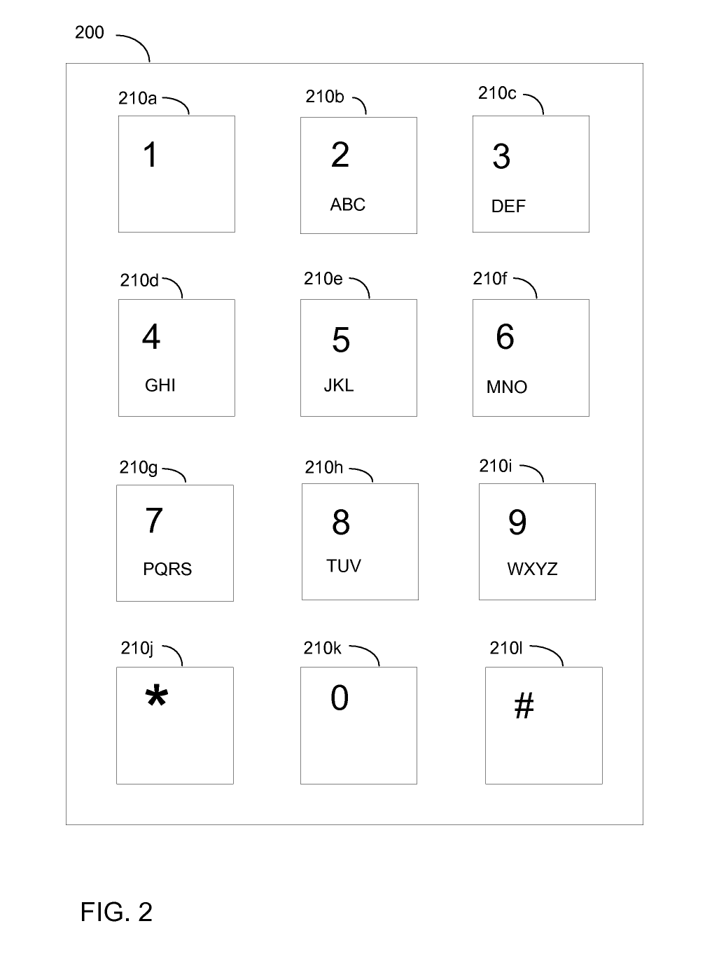

Referring now to FIG. 2, the dial pad 120 includes 12 switches, designated 210a-210l, typical of what is found on a telephone keypad. The switches contain a combination of alphabetic and numeric characters. For example, the dial pad switch “7” key 210g is shown as containing the number “7” and the letters “PQRS”. In example embodiments, the dial pad 120 can be configured to optimize entry of alphanumeric characters using the switches of the dial pad 120. For example, the dial page 120 can include combination touch sensitive and mechanical switches or two position switches that are used to determine the end of a keystroke, as described below.

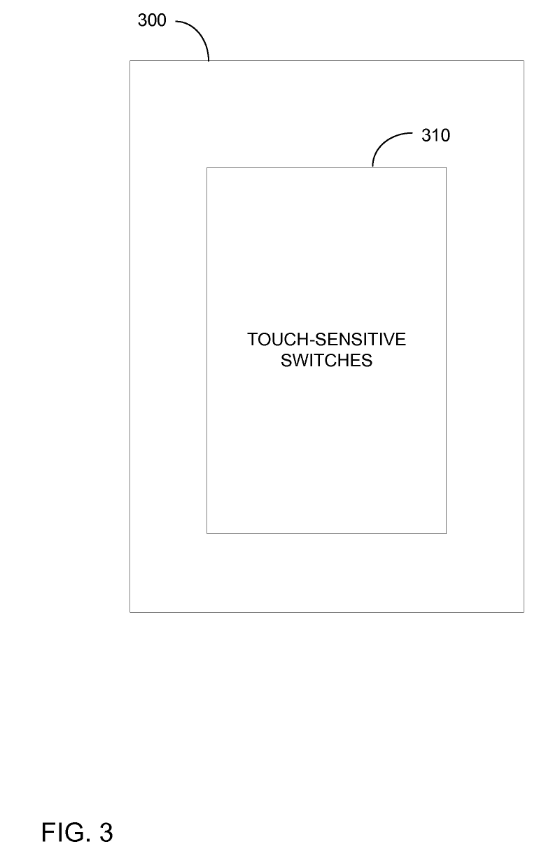

Referring now to FIG. 3, an example of a dial pad 300 including one or more touch sensitive switches 310 is shown. A touch sensitive switch can be used to determine when a user breaks physical contact with the dial pad key switch to reflect when a keystroke sequence is completed. For example, using a touch sensitive switch, as long as a user maintains touch contact (or close proximity) with the dial pad key switch (for example by pressing and releasing the dial pad key switch but keeping one's finger on the touch sensitive portion of the dial pad key switch), the keystroke sequence is designated as still active. But when a user removes touch contact with the switch (for example, by removing one's finger from the dial pad key switch), the keystroke sequence is designated as terminated.

As an alternative to a single switch, a touch sensitive device can also include an array of switches with touch or contact sensitivity. The aggregate input states of these switches are analyzed by hardware and software to determine the user's input intentions. Furthermore, the touch or contact sensitivity may only partially or completely cover one or more sides of the input key. The touch sensitive switches 310 can incorporate multiple sensor types as well as be implemented in configurations other than a square as shown, such as concentric rings, half circles, stripes across the key surface, or even a matrix of multiple sensor spot(s).

In example embodiments, the touch information from the touch sensitive switches 310 are used to expeditiously disambiguate users input intentions when using multifunction input keys. For example, if the user wants to enter the word “PRESS”, the user presses and releases the “7” key (the “7” touch sensitive switch) once and then breaks touch contact with the switch. This indicates to the communication device that the keystroke sequence is completed so that the character “P” is displayed on the device and the display cursor is advanced to the next position. The user then presses and releases the “7” key two consecutive times but maintaining touch contact with the touch sensitive switch. The user then presses and releases the “7” key one more time (for a total of three press and releases of the switch in this sequence) and then breaks touch contact with the switch. Breaking touch contact with the switch signifies the end of the keystroke sequence and since the “7” key was pressed a total of three times in this sequence before breaking contact, the character “R” is displayed and the cursor is advanced to the next position. Depending on the sensitivity and calibration of the touch system used, the user may be permitted to briefly break contact with the keys (for example in a finger bounce). In this situation, the system will treat the finger bounce as constant contact.

Using a touch sensitive switch in this manner can improve the efficiency of the dial pad data entry process because there is no delay between when one keystroke sequence ends and the next begins. Overall input speed can be improved because the user does not have to guess the time interval of the wait period between keystrokes. The user can enter keystrokes in a fast, efficient manner and does not need to rely on the display for visual indications.

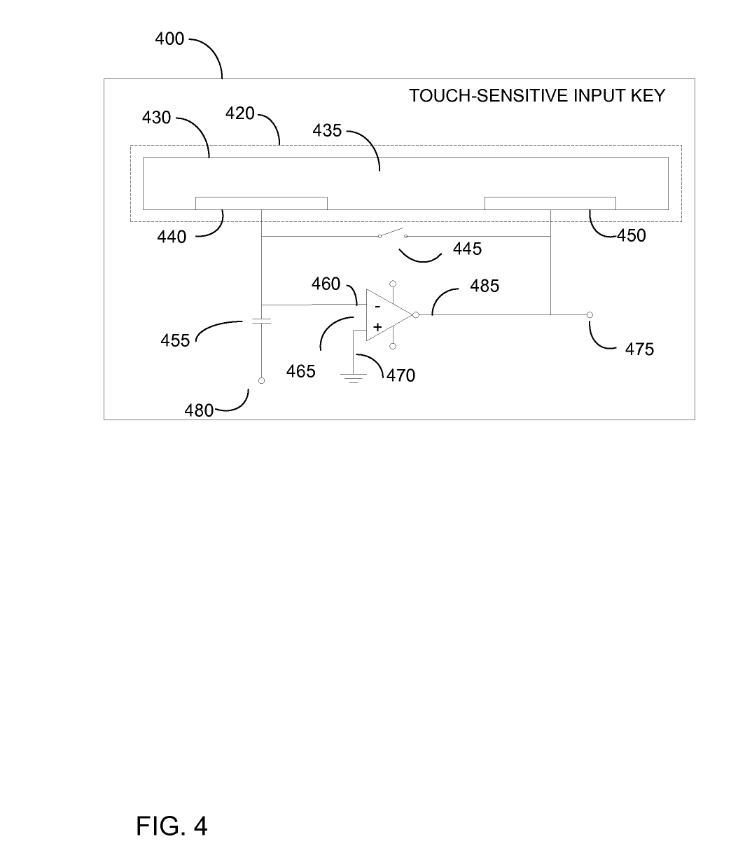

Referring now to FIG. 4, an example touch sensitive switch 400 is shown. This example switch includes a capacitive sensor 420 connected to an operational amplifier 465.

A surface 430 of a key or touch pad that is bonded or cooperatively coupled to a capacitive sensor 420. The example capacitive sensor 420 includes two conductor plates 440 and 450 surrounded by insulating material 435. The conducting plates 440 and 450 and the surrounding insulating material 435 form a capacitor. These components (i.e., 435, 440, and 450), along with a user finger interacting with the key, will effectively form a variable capacitor that when connected to an electrical sensing subsystem forms a capacitive sensor. This touch sensing circuitry can also be multiplexed and shared in part or whole across multiple input keys to reduce costs.

The feedback loop for the touch sensitive switch 400 is formed from the output 485 of operational amplifier 465, through the variable capacitor formed by conducting plate 450, insulator 435, conducting plate 440 and the user's finger, to the inverting input 460 of operational amplifier 465. The non inverting input 470 of operational amplifier 465 is connected to ground. In addition, a processor controlled switch 445 is used to temporarily bypass the capacitor in the feedback loop to balance the system. A terminal 480 functions as a reference voltage supply that is coupled via capacitor 455 to the inverting input 460 of the operational amplifier 465.

The determination of whether a user is making touch contact with the switch 430 is made by examining the operational amplifier output terminal 475 as follows. A touch sense cycle begins when a processor (not shown) momentarily closes the switch 445 to balance the system. Next, the processor opens switch 445 and the capacitors charge up due to the input reference voltage at source 480. The movement of the user's finger in relation to the switch (i.e., closer or farther away from the switch) changes the capacitance seen at plates 440, 450 and causes greater or lesser capacitance in the feedback loop. This changes the voltage at the inverting input 460 of operational amplifier 465, which in turn changes the output voltage measured at operational amplifier output 475. A processor senses the voltage at operational amplifier output 475 to determine whether or not touch contact is being made with the switch.

The example touch sensitive switch 400 can be modified as desired in a particular application. For example, depending on the resolution desired for the shape or texture of the object touching the device, the number of sensor arrays may increase. As another example, an electronic fingerprint reader may incorporate circuitry similar to that illustrated in FIG. 4. In such an embodiment, the finger print reader's contact sensing functionality may be reused as a generic contact sensing surface for an application like a touch sensitive switch.

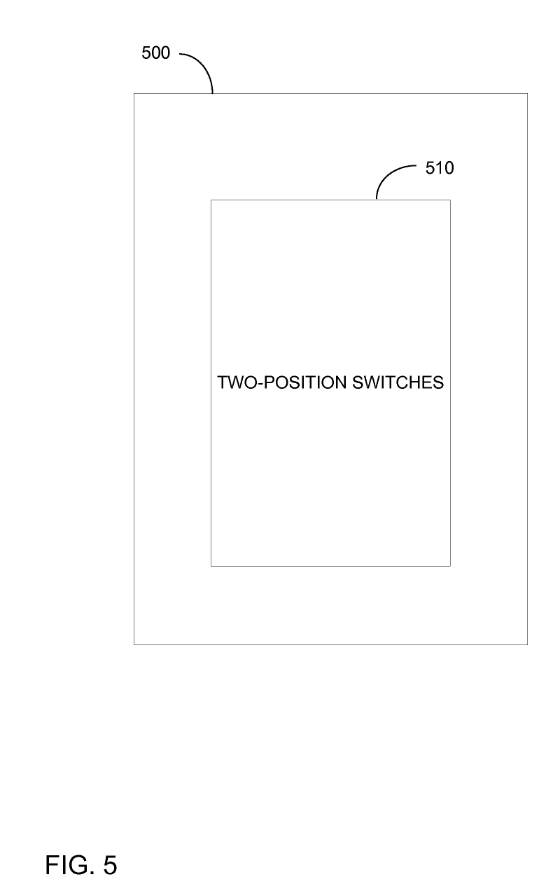

Referring now to FIG. 5, in another example embodiment, a dial pad 500 including a plurality of two position switches 510 can be used to determine when a keystroke sequence is completed.

An example two position switch is in a first position when the switch is pressed halfway down and is in a second position when the switch is pressed all the way down. When used in this example embodiment, a user presses the switch halfway down to begin the keystroke sequence. The user then presses the switch all the way down to the second position but only releases the switch halfway up so that it is back in the first position. This constitutes depressing the switch once. If the user needs to continue the keystroke sequence, the switch is pressed down again to the second position and released back to the first position. Whenever, the user determines that the keystroke sequence is completed (i.e., when the user has pressed the switch to the second position and back to the first position the required number of times), the user releases the switch all the way back to the starting position. This completes the keystroke sequence.

For example, if the user wanted to enter the character “N”, the “6” key is pressed two times since “N” is the second character on the “6” key. For the first keystroke, the “6” key is pressed halfway down to the first position and while the key is held in this state the display shows no input from the “6” key. The keystroke sequence then continues by pushing the key further down to the second position which results in the display showing an “M.” The key is then released from the second position and returned back to the first position. Next the “6” key is pressed the to the second position again, at which time the display shows the next input available from the “6” key which is the desired character “N.” Finally the “6” key is completely released from the second position and returned to the starting position, signaling the end of the multifunction keystroke sequence. The input value “N” is displayed and the cursor is advanced to the next position.

Alternative embodiments are possible. For example, in the previous example, during the first keystroke of the sequence, when the “6” key is pressed halfway down to the first switch position, the device could display the input value “M” rather than waiting until the key is pressed to the second position. This speeds the user input by displaying the first value on the half key press and the second value at the time the key is pressed to the second position. Subsequent multifunction input values would be displayed each time the key is pressed from the first switch position to the second switch position. When the keystroke sequence is completed, the “6” key is completely released so that it is neither in second or first switch positions. At this point, the input value “N” is displayed and the cursor is advanced to the next position.

In another embodiment, the second switch position can be used to terminate the multifunction input key sequence. Each time a key is pressed to the first switch position, the multifunction key displays one of the possible values. The key is then released and pressed again to the first switch position to display the next possible value. Finally when the desired value is presented, the key is pressed to the second switch position which terminates the keystroke sequence and advances the cursor. The following example describes how this example could be applied to expedite inputting the letter “N”. Initially, the “6” key is pressed half way to the first switch position, at which time the display would show the letter “M”. Next, the “6” key is completely released. Next, the “6” key is pressed a second time to the first switch position, at which time the display would show the letter “N”. The “6” key is then pressed to the second switch position to terminate the keystroke sequence and then the “6” key is completely released. The software monitoring the key in the second switch position uses this event to detect that the keystroke sequence has ended, and then advances the cursor. If the “6” key is pressed again, the entry would be a new input selection process, and start by displaying the letter “M”.

In alternative embodiments, switches have three or more positions can also be used in a similar manner. For example, a three position switch can be used as follows. The first position can be used as a state in which the user has not yet released the switch to signify the end of a keystroke sequence. The second position can be used as a neutral position at which the user rests between keystrokes. The third position can be used to signify a change in input state. Other configurations are possible.

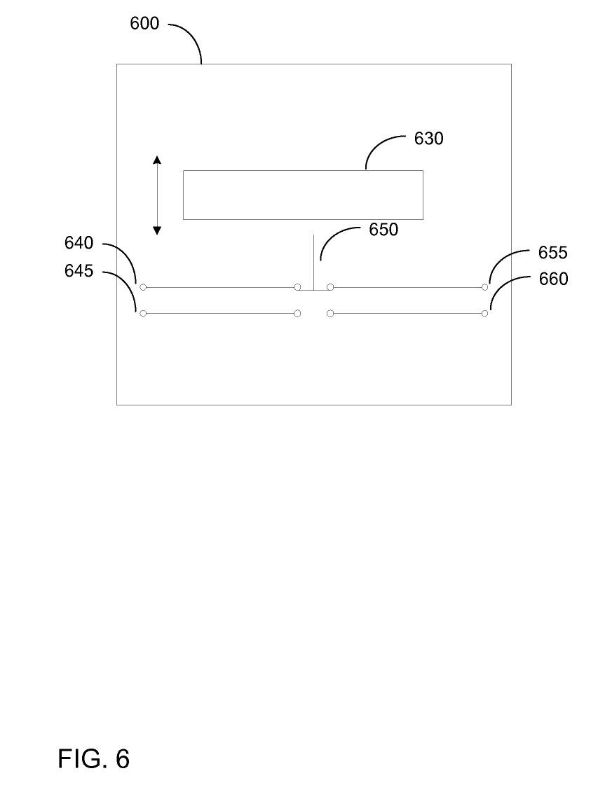

FIG. 6 an example of a two position switch cooperatively coupled with an input key surface. A dial pad 600 includes an input key surface 630 is coupled to a switch mechanism 650 commonly known as a pushbutton two circuit switch. References 640 and 655 represent the two poles of the first switch position, normally closed in this example. The two poles of the second switch position are represented by references 645 and 660. When the user presses key surface 630 to the first switch position, an electrical connection is broken between poles 640 and 655, and there is an open circuit between poles 645 and 660. When the user presses the key surface 630 to the second switch position, there is an electrical connection made between poles 645 and 660 and there is an open circuit between poles 640 and 655.

The switch mechanism 650 can be designed such that it requires different amounts of user effort or touch sensation to move the switch to each position. The different amount of effort and key travel provides the user with a rich tactile sensation as the key state changes and as the user maintains a given state. The amount of key travel required between the first and second switch positions can be modified by layering two differently designed switches or by a combination switch with these desired attributes.

In alternative embodiments, an array of input switch mechanisms with different states, or more than two states can be used, if desired. For example, momentary switches, contact and non-contact switches, and layering multiple single/dual action switches can be used. Other combinations of switches which are normally open, closed, momentary, single pole single throw, double pole single throw, selector switches etc. can also be used. These switches can be connected as inputs into a computational device which monitors the state and state changes using hardware and software means. The input sense and actuation mechanisms can include electrical and mechanical means which include but not limited to electromagnetic field sensors, infrared sensors, and optical switches as well as traditional contacts, membrane switches and the like.

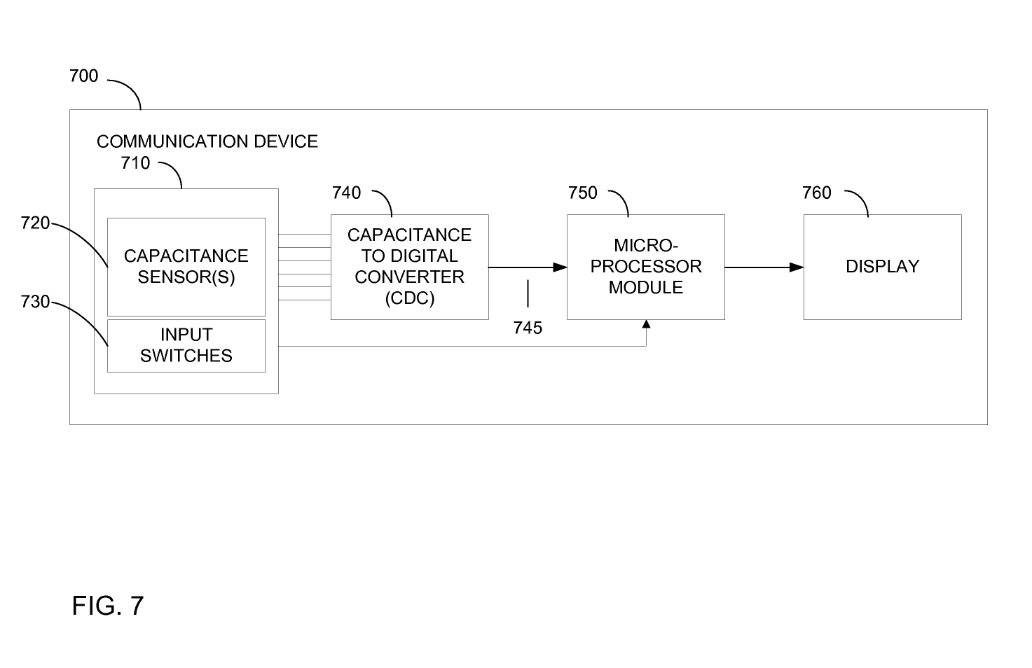

FIG. 7 shows an alternative example communications device 700 including touch sensitive switch module 710, a microprocessor module 750, and an optional display 760. The touch sensitive switch module 710 may contain either a capacitance sensor or array of sensors 720, as well as input switches 730 of various designs and attributes. The touch sensitive switch module 710 may cooperatively couple one or more input switches 730 with respective capacitance sensors 720, enabling touch or contact sensitivity to predefined input actions. The capacitance sensor component is monitored by a capacitance-to-digital-converter (CDC) 740 and interfaces with the microprocessor module 750. The microprocessor module 750 contains a microprocessor, random access memory (RAM), read only memory (ROM) and input buffering circuitry to detect and de-bounce inputs from component 730. The microprocessor module 750 also contains software programs and software drivers associated with enabling the touch sense functionality provided by the sensors 720 and the CDC 740. Additional computer readable media, such as RAM or ROM, can also be provided.

Each time a user presses and releases an input key of touch sensitive switch module 710, a signal identifying the switch is sent to the microprocessor module 750. Additionally, contact or touch information may be sent to the microprocessor module 750. The signal and contact or touch information may be buffered by intermediate electronic circuitry as part of the touch sensitive switch module 710 and/or the CDC 740. In addition, when the keystroke sequence is completed, for example by breaking touch contact for a touch sensitive switch or by pressing the key all the way down for a two position switch, another signal is made available to the microprocessor module 750. These signals can be interrupt signals or they can be polled by the processor 750. The microprocessor module 750 monitors and analyzes the data available from the input keys and touch sensors and determines the input function or character that corresponds to the keystroke sequence. The microprocessor module 750 then causes the character to be displayed on the display 760 and advances the display cursor to the next character position.

The microprocessor module 750 is used to execute software programs which control how actions at the switch component 710 are displayed on component 760. Additionally, the input subsystem 710 and 740 can be coupled in implementations using a proprietary or standards-based connection interface such as Bluetooth (IEEE 802.15.1), USB, I²C or other common interconnect as shown at component 745 to become a common input peripheral with advanced input capability. The interconnect component 745 may include a subsystem such as an application specific integrated circuits (ASIC) or microprocessor. Additionally component 760 is shown as a display device, however it should be understood that it also represents a generic output of the component 750 which is a hardware and/or software derivative of manipulations of input component 710. The information output to component 760 can also be used by component 750 internally as well as made available to other systems using networking such as Ethernet (IEEE 802.3), Bluetooth, USB, WiFi (IEEE 802.11.x).

The touch sensing system shown in FIG. 7 can be created using commercially available special purpose semiconductor devices such as the Analog Devices AD7142 Programmable Controller for Capacitance Touch Sensors. These devices, represented by component 740, are specialized capacitance to digital converters (CDCs) with on-chip environmental compensation as well as many other features useful to touch sensitive input applications such as having the capability to automatically adjust to individual finger sizes. The functionality of these devices may be used as discrete components in a design or integrated into a complete system on a chip (SOC) design, stacked part, or other method commonly used to efficiently deliver hardware and software integration in a device.

Although FIG. 7 shows an example of a capacitance sensor, touch sensitivity can be achieved using other physical to electrical interface techniques such as infrared emitter/detector pairs which monitor a return signal to detect contact with surfaces. In addition, the present application can be applied to a general class of device and therefore component 700 should not be considered limited to a communication device as shown.

In another example embodiment, dial pads can contain function keys in addition to or in combination with alphanumeric keys. Function keys can be overloaded in the same manner as alphanumeric keys to represent multiple functions. For example, a dial pad key may contain a Back Arrow symbol and a Page Down symbol. Executing the Back Arrow command would move the cursor one position to the left. Executing the Page Down command would scroll down one page of text on the display of the communication device.

If a user presses this overloaded function key, the communication device needs to distinguish between the two functions. In an example embodiment, where the overloaded function keys are touch sensitive switches, if the user presses and releases the switch once and then breaks touch contact with the switch, the communication device interprets the keystroke sequence as representing the Back Arrow command. Instead, if the user pressed and released this switch two times, breaking touch contact with the switch after the second keystroke, the communication device interprets the keystroke sequence as representing the Page Down command.

In the example embodiment where the overloaded function keys are two position switches, if the user makes one keystroke, pressing the switch all the way down through the first switch position and the second switch position and releasing it completely, the communication device interprets the keystroke sequence as representing the Back Arrow command. Instead, if the user presses the key to the first position, then presses the key to all the way down to the second position, then only releases it back to the first position, then presses it to the second position and then releases the key completely, the communication device interprets the keystroke sequence as representing the Page Down command.

In the example embodiment where the multifunction input keys are two position switches, system software can enter a mode where keystrokes can be distinguished between the non-shifted characters (i.e. lower case “a”) and the shifted characters (i.e. upper case “A”). In this example, pressing a key to the first position would result in the non shifted characters (i.e. lower case “a”), while pressing the key to the second position would directly result in a shifted characters (i.e. upper case “A”). Similar features could be controlled in software for other multifunction keys.

In such embodiments, devices other than handheld devices including a dial pad can be used. For example, a two position switch can be incorporated into a full or partial keyboard to differentiate between lower and upper case characters, as described above. Other configurations are possible.

In another alternative embodiment, a touch button is used to distinguish the end of a keystroke sequence. When the touch button is depressed, a signal is sent to the microprocessor module. For example, if the letter “K” is to be entered, the user presses the “5” key two times and then depresses the touch button. When the microprocessor module receives a signal from the touch button, the timeout wait is immediately ended, and the cursor is advanced to the next position. The “5” key becomes immediately available to input the letter “J” with a single keystroke.

Various types of switches can be used in the systems and methods disclosed in the present application. Some examples of technology used in touch (proximity) sensitive switches include capacitive coupling, variable electrical resistance, pressure sensing, light sensing, and heat sensing. The devices can include capacitance scanning.

In one example, a touch sensitive switch can contain an electrical sensor that monitors electrical capacitance between the user and the switch. A capacitor contains two plates and a dielectric material between the plates. In a capacitive touch switch, one or more capacitors are wired into the switch. The capacitance of the switch is monitored by the electrical sensor. When a user touches the switch, the capacitance of the switch changes and this change is sensed by the electrical sensor. In this manner the electrical sensor can determine when the user is in touch-contact (or close proximity) with the switch and can determine when touch contact is broken.

In another example, a touch sensitive switch can contain a pressure sensor. The pressure sensor can detect pressure on the surface of the switch, such as when a user maintains contact with the switch. The pressure switch can detect a change in pressure when the user breaks touch contact from the switch, such as by removing the user's finger from the switch. The variable pressure can result in detectable electrical properties such as changes in inductance, capacitance, resistance, etc.

In another example, a touch sensitive switch can contain a light source and light sensor. In this example, the top of the switches is semi-transparent. A light source built into the switch emits light within the switch. Part of this light is reflected by the top surface of the switch. The reflected light is monitored. When a user touches the switch, the reflection coefficient of the light changes. This change in reflection coefficient provides an indication of when touch contact with the switch is made and when touch contact with the switch is broken. In this example, the light source can contain white light or components of the visible spectrum or it can contain infra-red light, or even UV light. These light sources can be from such sources as Light Emitting Diodes (LEDs) and include those which emit different wavelengths of light including selections from the visible, infrared or even ultraviolet (UV) spectrum. The light detectors can be simple LED, or specifically designed light detecting semiconductor devices. The LED and detector pairs can also be integrated into a single package or array of emitter/detector pairs.

In yet another example, a touch sensitive switch can contain a heat sensor. In this example, the switch can detect the heat from the user's finger and thus determine when the user is making and breaking touch contact with the switch. These types of switches include comparator algorithms or circuitry to detect the delta between the ambient heat detected by all the other keys and the specific one(s) being actuated.

In examples including two position switches, a switch containing Hall-effect sensors can be used. A Hall-effect sensor is a transducer that varies its output voltage in response to changes in a magnetic field. In an example two position switch, Hall-effect sensors are located at a first position (corresponding to depressing the switch half-way down) and at a second position (corresponding to depressing the switch all the way down). A magnet in the switch detects an increased voltage from the sensor in the first position when the switch is pressed half-way down and it detects an increased voltage from the sensor in the second position when the switch is pressed all the way down. In this manner, a first signal is generated when the switch is in the first position and a second signal is generated when the switch is in the second position.

It should be appreciated the input switch mechanisms of the present application can include layering touch sensitive switches over an existing input keyboard switch technology to realize the benefits of the enhanced multifunction input selection, in addition to designing compound multi-state input switch designs.

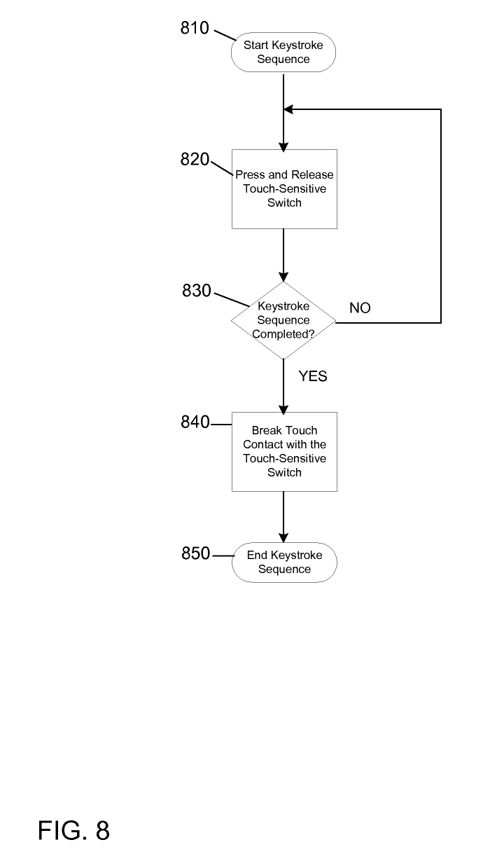

FIG. 8 shows an example method of a keystroke input sequence using touch sensitive switches. The sequence starts at operation 810. The user presses and releases a touch sensitive switch at operation 820, but maintains touch contact with the switch. It should be appreciated that the touch sensitive surface and monitoring system can be designed and calibrated so that maintaining touch contact can include both actual physical contact as well as the user's finger staying within a close proximity from the target key. At operation 830, a decision is made as to whether this is the last keystroke in the keystroke sequence. If additional keystrokes need to be entered before the sequence is completed, the user enters another keystroke at operation 820, while still maintaining touch contact with the switch. However, if the keystroke sequence is completed, meaning that the user has entered the required number of keystrokes corresponding to the character or function to be entered, the user at operation 840 breaks touch contact with the switch. This ends the keystroke sequence at operation 850.

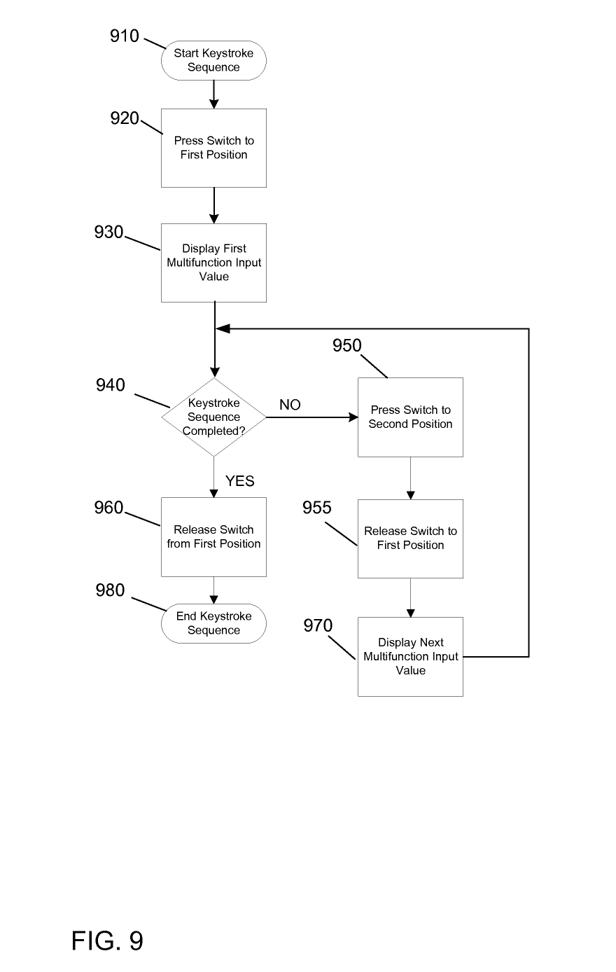

FIG. 9 shows an example method of a keystroke input sequence using two position switches. The user presses the two position switch half-way down to the first position at operation 920 at which time the first input value possible for the key is selected and or displayed at operation 930. At operation 940, a decision is made as to whether this is the last keystroke in the keystroke sequence. If it is not the last keystroke in the keystroke sequence, at operation 950 the user presses the key further to the second switch position. Then, at operation 955, the user releases the key back to the first switch position and maintains the key at the first key position. At operation 970, the system displays to the user the next input value possible from the multifunction key. After operation 970, the flow advances to operation 940 where the user decides if the keystroke sequence has been completed. In this fashion the user can alternate through all the values offered by the multifunction key by repeatedly pressing the key to the second switch position and releasing the key to the first switch position, thereby effectively looping through operations 940, 950, 955 and 970 until the desired value is selected. The color or intensity of the value may be noticeable to the observer while in the keystroke selection sequence if it is displayed on a screen or alphanumeric output panel. At operation 940, if it is determined that this is the last keystroke in the sequence, the user ends the keystroke sequence by releasing the key from the first position switch at operation 960, returning the key to the starting position. The keystroke sequence then ends at operation 980. If the user presses any key the keystroke sequence starts again at operation 910.

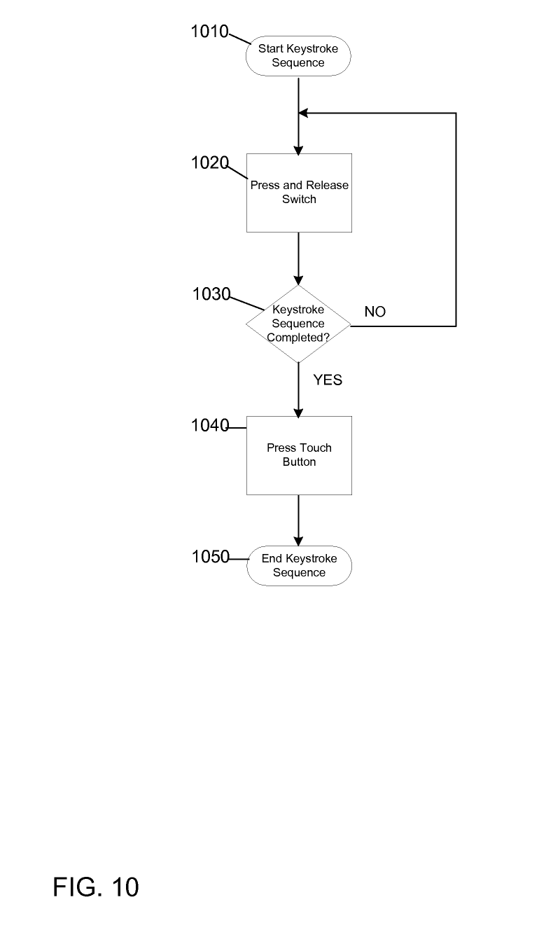

FIG. 10 shows an example method of a keystroke input sequence using a touch button. The sequence starts at operation 1010. At operation 1020, the user presses an overloaded alphanumeric or function switch. At operation 1030, a decision is made as to whether this is the last keystroke in the keystroke sequence. If additional keystrokes need to be entered before the sequence is completed, the user enters another keystroke at operation 1020. However, if the keystroke sequence is completed, meaning that the user has entered the required number of keystrokes corresponding to the character or function to be entered, the user at operation 1040 presses the touch button. Next, the keystroke sequence ends at operation 1050.

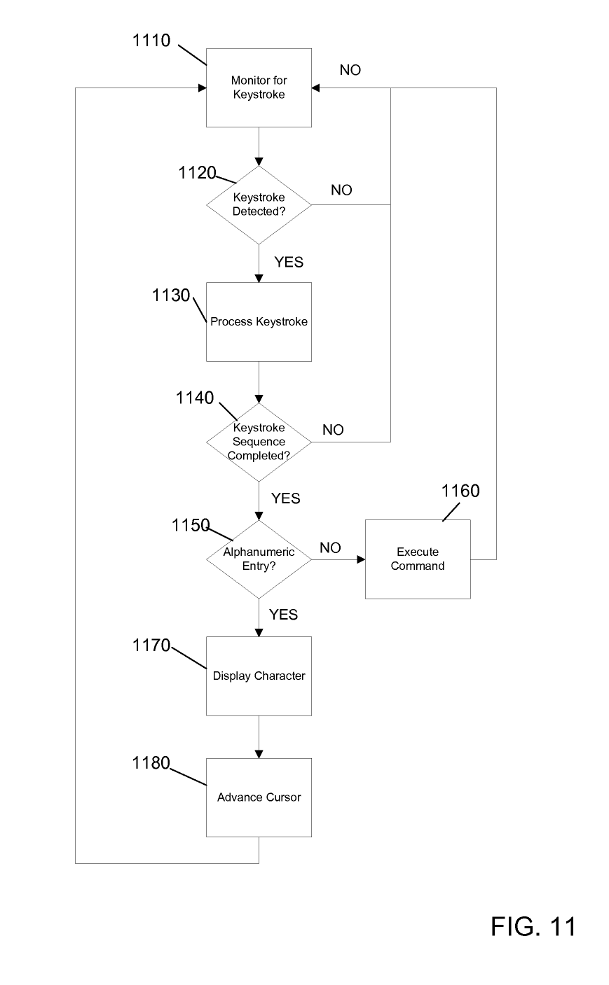

FIG. 11 shows an example keystroke input process for a communication device. The microprocessor of the communication device continually monitors for user keystrokes (or waits for an interrupt) at operation 1110. If a keystroke is detected at operation 1120, the keystroke is processed at operation 1130 to determine the key that was pressed, the number of times the key was pressed in the keystroke sequence and whether a signal was sent from the key indicating that this was the last keystroke in the sequence. At operation 1140, a determination is made as to whether the keystroke was the last keystroke in the sequence. For example, if touch sensitive switches are used, a determination is made at operation 1140 as to whether or not the user has broken contact with the switch, thereby indicating the end of the keystroke sequence.

If this was not the last keystroke in the keystroke sequence, the communication device monitors for the next keystroke at operation 1110. However, if this was the last keystroke in the keystroke sequence, a determination is made at operation 1150 as to whether the keystroke sequence represented an alphanumeric key or a function key. If the keystroke sequence was for a function key, the command associated with that function (for example moving the cursor or scrolling text down a page) is executed at operation 1160. If the keystroke sequence was for an alphanumeric key, the appropriate character is displayed on the communication device (operation 1170) and the cursor is advanced (operation 1180).

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A communication device, comprising:
a dial pad including a plurality of touch sensitive switches;
a display; and
a microprocessor module;
wherein one switch of the touch sensitive switches provides a signal to the microprocessor module when a user breaks touch contact with the switch, the breaking of touch contact with the switch signifying that a keystroke sequence is completed.

2. The device of claim 1, wherein a cursor on the display is advanced when the user breaks touch contact with the switch.

3. The device of claim 1, wherein a command is executed when the user breaks touch contact with the switch.

4. The device of claim 1, wherein each switch of the plurality of touch sensitive switches contains an electrical sensor, the electrical sensor providing capacitive coupling between the user and the switch.

5. The device of claim 1, wherein each switch of the plurality of touch sensitive switches contains a pressure sensor.

6. The device of claim 1, wherein each switch of the plurality of touch sensitive switches contains a light sensor.

7. The device of claim 6, wherein the light sensor uses an infra-red light.

8. The device of claim 1, wherein each switch of the plurality of touch sensitive switches contains a heat sensor.

9. A method for interpreting keystrokes from a plurality of touch sensitive switches, the method comprising:
monitoring for a keystroke from a switch;
processing a first signal each time the switch is pressed and released;
monitoring when a user breaks touch contact with the switch; and
processing a second signal when the touch contact is broken with the switch, the breaking of the touch contact with the switch signifying that a keystroke sequence is completed.

10. The method of claim 9, further comprising advancing a cursor position when touch contact is broken with the switch.

11. The method of claim 9, further comprising executing a command when touch contact is broken with the switch.

12. The method of claim 9, wherein monitoring when the user breaks the touch contact further comprises monitoring a capacitive coupling between the user and the key to monitor when the user breaks the touch contact.

13. The method of claim 9, wherein monitoring when the user breaks the touch contact further comprises monitoring a pressure between the user and the key to monitor when the user breaks the touch contact.

14. The method of claim 9, wherein monitoring when the user breaks the touch contact further comprises monitoring a light emitted from the key to monitor when the user breaks the touch contact.

15. The method of claim 14, wherein the light is an infra-red light.

16. The method of claim 9, wherein monitoring when the user breaks the touch contact further comprises monitoring heat from the key to monitor when the user breaks the touch contact

17. A method for interpreting keystrokes from a plurality of two position switches, the method comprising:
monitoring for detection of a switch in a first position;
processing a first signal each time the switch is in the first position;
monitoring for detection of the switch in a second position;
processing a second signal when the switch is in the second position;
monitoring for detection of the switch in a starting position after it has been detected in the first position; and
processing a third signal when the switch is detected in a starting position after it has been detected in a first position, the detection of the switch in the starting position after it has been detected in the first position signifying completion of a keystroke sequence.

18. The method of claim 17, further comprising displaying a character when the switch is in the first position.

19. The method of claim 17, further comprising advancing a cursor when the switch is detected in the starting position after detecting the switch in the first position.

20. The method of claim 17, further comprising executing a command on a communication device when the switch is detected in the starting position after detecting the switch in the first position.
